(19) United States
(12) Patent Application Publication
(10) Pub. No.: US 2014/0166205 A1
(43) Pub. Date: Jun. 19, 2014

(54) PROCESS MONITORING DEVICE FOR USE IN SUBSTRATE PROCESS APPARATUS, PROCESS MONITORING METHOD AND SUBSTRATE PROCESSING APPARATUS

(71) Applicants: Caizhong Tian, Osaka (JP); Toshihisa Nozawa, Sendai (JP); Kazuki Moyama, Sendai (JP); Takahiro Senda, Sendai (JP); Kazuyuki Kato, Sendai (JP); Munetaka Yamagami, Tokyo (JP)

(72) Inventors: Caizhong Tian, Osaka (JP); Toshihisa Nozawa, Sendai (JP); Kazuki Moyama, Sendai (JP); Takahiro Senda, Sendai (JP); Kazuyuki Kato, Sendai (JP); Munetaka Yamagami, Tokyo (JP)

(73) Assignee: TOKYO ELECTRON LIMITED, Tokyo (JP)

(21) Appl. No.: 14/111,030

(22) PCT Filed: Apr. 6, 2012
(86) PCT No.: PCT/JP2012/059495

§ 371 Date: Oct. 30, 2013

(30) Foreign Application Priority Data
Apr. 11, 2011 (JP) 2011-087179

(51) Int. Cl. G01B 11/24; H01J 37/32

(52) U.S. Cl. CPC G01B 11/24; H01J 37/32009
USPC 156/345.24; 356/601

(57) ABSTRACT

A process monitoring device 11 includes a light source unit that outputs light; a light detection unit that detects an intensity of light; a first optical path 21 that guides the light outputted from the light source unit to a wafer W and guides reflection light from the wafer W to the light detection unit; a second optical path that has a light propagation characteristic equivalent to that of the first optical path 21 and guides the light outputted from the light source unit to the light detection unit without allowing the light to pass the wafer W; and a controller 17 that corrects intensity information of the light detected by the light detection unit via the first optical path 21 based on intensity information of the light detected by the light detection unit via the second optical path, and analyzes a structure of the wafer W.

### TECHNICAL FIELD

The embodiments described herein pertain generally to a process monitoring device for use in a substrate processing apparatus, a process monitoring method and a substrate processing apparatus. The embodiments particularly pertain to a process monitoring device, a process monitoring method and a substrate processing apparatus for investigating a structure of a processing target substrate.

### BACKGROUND ART

In the field of semiconductor manufacture, there has been an increasing demand for advanced level of miniaturization and densification of semiconductor devices. Under this circumstances, in order to manufacture a semiconductor device having a higher added value, a thickness of a film formed by, e.g., a CVD (Chemical Vapor Deposition) process, a thickness of a film when performing an etching process, a structure of a wafer surface, and so forth are measured during the processes, and by comparing the measured values with reference values, various kinds of processing parameters are corrected. For this purpose, conventionally, there has been developed a process monitoring device configured to investigate a surface structure of a wafer by irradiating light to the wafer and by detecting and analyzing reflection light from the wafer. As one example, described in Japanese Patent Laid-open Publication No. 2005-033187 (Patent Document 1) is a device and a method for measuring a surface structure of a wafer by using an optical method such as ellipsometry.

Patent Document 1: Japanese Patent Laid-open Publication No. 2005-033187

### DISCLOSURE OF THE INVENTION

### Problems to be Solved by the Invention

Besides the device described in Patent Document 1, in a process monitoring device that measures a structure of a processing target substrate by using an optical method, the following problems may occur, and, accordingly, it is not possible to perform an accurate measurement.

In order to irradiate light to a surface of the processing target substrate while processing the processing target substrate, it is required to introduce light into a processing vessel from a light source. In general, the light source and the processing vessel are connected by using an optical fiber cable.

Here, if the optical fiber cable is used continuously over time, since the optical fiber cable would be damaged and degraded by an ultraviolet component of the light as time goes on, the ultraviolet component passing through the optical fiber cable is gradually reduced. Thus, while using the device for a long time, in case of detecting an intensity spectrum of reflection light from the processing target substrate and analyzing the surface structure of the processing target substrate by using, as one parameter, the intensity information, the surface structure of the processing target substrate may not be measured accurately. Particularly, when measuring a thickness of a very thin film in a range of several nanometers, an ultraviolet ray having a shorter wavelength needs to be used. Thus, if the ultraviolent component of the light is reduced, an error may occur in the measurement result. Therefore, it is not possible to perform the accurate measurement.

In view of the foregoing problems, example embodiments provide a process monitoring device configured to measure a structure of a processing target substrate with higher precision by using an optical method.

The example embodiments also provide a process monitoring method that investigates a structure of a processing target substrate with higher precision by using an optical method.

The example embodiments further provide a substrate processing apparatus configured to investigate a structure of a processing target object with higher precision by using an optical method.

### Means for Solving the Problems

In one example embodiment, a process monitoring device investigates a structure of a processing target substrate by irradiating light to a surface of the processing target substrate provided within a processing vessel of a substrate processing apparatus and detects reflection light from the processing target substrate. The process monitoring device includes a light source unit configured to generate and output light; a light detection unit configured to detect an intensity of light inputted from an outside thereof; a first optical path configured to guide the light outputted from the light source unit to the processing target substrate and guide the reflection light from the processing target substrate to the light detection unit; a second optical path that is formed to have a light propagation characteristic equivalent to that of the first optical path and is configured to guide the light outputted from the light source unit to the light detection unit without allowing the light to pass the processing target substrate; and a controller configured to correct intensity information of the light detected by the light detection unit via the first optical path based on intensity information of the light detected by the light detection unit via the second optical path, and configured to analyze the structure of the processing target substrate.

With this configuration, a variation of a light intensity caused by the aging and the degradation of the first optical path as a result of a continuous use can be accurately measured by measuring a variation of an intensity of the light detected by the light detection unit via the second optical path having the light propagation characteristic equivalent to that of the first optical path. As a result, based on the variation information, it is possible to correct the intensity information of the light detected by the light detection unit via the first optical path. That is, since an influence of the aging and the degradation of the first optical path can be excluded from the intensity information of the light detected by the light detection unit via the first optical path, it is possible to measure an intensity of the reflection light from the processing target substrate. Thus, the structure of the processing target substrate can be investigated with high precision.

Desirably, each of the first optical path and the second optical path may include an optical fiber cable, and the optical fiber cables may be made of the same material and have the same total length. With this configuration, since the first optical path and the second optical path are made of the same material having the same light propagation characteristic, the variation of the light intensity caused by the aging and the degradation of the first optical path can be more accurately detected. Thus, the structure of the processing target substrate can be investigated with higher precision.

Desirably, the process monitoring device may further include a first mirror disposed to reflect the light outputted from the light source unit and configured to change a reflection direction of the light; and a second mirror disposed to further reflect the light reflected by the first mirror. The first mirror may be configured to periodically change the reflection direction of the light between a reflection direction toward the processing target substrate and a reflection direction toward the second mirror. Further, the first optical path may be configured to guide the light outputted from the light source unit to the processing target substrate via the first mirror and configured to guide the reflection light from the processing target substrate to the light detection unit. Furthermore, the second optical path may be configured to guide the light outputted from the light source unit to the light detection unit via the first mirror and the second mirror.

More desirably, the process monitoring device may further include an optical fiber cable configured to guide the light outputted from the light source unit to the first mirror. The first optical path may be configured to guide the light outputted from the light source unit to the processing target substrate via the optical fiber cable and the first mirror, and configured to guide the reflection light from the processing target substrate to the light detection unit via the first mirror and the optical fiber cable. Further, the second optical path may be configured to guide the light outputted from the light source unit to the second mirror via the optical fiber cable and the first mirror, and configured to guide the reflection light from the second mirror to the light detection unit via the first mirror and the optical fiber cable.

With this configuration, since the first optical path and the second optical path can share the optical fiber cable in common, the variation of the light intensity caused by the aging and the degradation of the first optical path can be detected more accurately. Thus, it is possible to investigate the structure of the processing target substrate with higher precision. Further, since the first optical path and the second optical path can be switched by controlling the first mirror configured to change the reflection direction of the light, it is possible to control the investigation of the structure of the processing target substrate as required. Furthermore, since a part of the first optical path and the second optical path is shared therebetween and the first optical path and the second optical path can be switched by using a simple mirror member, a structure of the process monitoring device can be more simplified.

Desirably, the controller may be configured to analyze the structure of the processing target substrate by correcting the intensity information of the light detected by the light detection unit via the first optical path based on a difference between the intensity information of the light detected by the light detection unit via the second optical path and intensity information of light detected by the light detection unit via the second optical path at the time of starting a process. With this configuration, it may be possible to accurately detect a variation of the light intensity after starting the process when the aging and the degradation does not occur. Accordingly, the influence of the aging and the degradation of the first optical path can be excluded more securely. Thus, the structure of the processing target substrate can be investigated with higher precision.

Desirably, the light generated by the light source unit may have a wavelength equal to or smaller than about 300 nm. With this configuration, by using the light having a relatively short wavelength, a structure with a smaller dimension can be investigated.

In another example embodiment, a process monitoring method investigates a structure of a processing target substrate by irradiating light to a surface of the processing target substrate provided within a processing vessel of a substrate processing apparatus and detects reflection light from the processing target substrate. The process monitoring method includes a first optical path passing process that guides light outputted from a light source unit to the processing target substrate and guides the reflection light from the processing target substrate to a light detection unit configured to detect an intensity of light; a second optical path passing process that guides light outputted from the light source unit to the light detection unit without allowing the light to pass the processing target substrate; and an analyzing process that analyzes the structure of the processing target substrate by correcting intensity information of the light detected by the light detection unit through the first optical path passing process based on intensity information of the light detected by the light detection unit through the second optical path passing process. Further, a first optical path through which the light passes in the first optical path passing process and a second optical path through which the light passes in the second optical path passing process are formed to have the same light propagation characteristic.

With this configuration, a variation of a light intensity caused by aging and degradation of the first optical path as a result of a continuous use can be accurately measured by measuring a variation of an intensity of the light detected by the light detection unit via the second optical path having the light propagation characteristic equivalent to that of the first optical path. As a result, based on variation information, it is possible to correct the intensity information of the light detected by the light detection unit through the first optical path passing process. That is, since an influence of the aging and the degradation of the first optical path can be excluded from the intensity information of the light detected by the light detection unit through the first optical path passing process, it is possible to measure an intensity of the reflection light from the processing target substrate. Thus, the structure of the processing target substrate can be investigated with high precision.

Desirably, each of the first optical path and the second optical path may include an optical fiber cable, and the optical fiber cables may be made of the same material and have the same total length. With this configuration, since the first optical path and the second optical path are made of the same material having the same light propagation characteristic, the variation of the light intensity caused by the aging and the degradation of the first optical path can be more accurately detected. Thus, the structure of the processing target substrate can be investigated with higher precision.

Desirably, the first optical path passing process may include guiding the light outputted from the light source unit to a first reflection member configured to change a reflection direction of the light; reflecting the light toward the processing target substrate by the first reflection member; and guiding the reflection light from the processing target substrate to the light detection unit. Further, the second optical path passing process may include guiding the light outputted from the light source unit to the first reflection member; reflecting the light from the first reflection member toward a second reflection member configured to further reflect the reflection light from the first reflection member; and guiding the reflection light from the second reflection member to the light detection unit. Furthermore, the first reflection member may be controlled to periodically change the reflection direction of the light between a reflection direction toward the processing target substrate and a reflection direction toward the second reflection member. More desirably, in the first optical path passing process, the reflection light from the processing target substrate may be guided to the light detection unit via the first reflection member, and in the second optical path passing process, the reflection light from the second reflection member may be guided to the light detection unit via the first reflection member.

With this configuration, in the first optical path passing process and the second optical path passing process, an optical path between the light source unit and the first reflection member can be shared. That is, it is possible to form this common optical path with, by way of example, but not limitation, a single optical fiber cable. Accordingly, the variation of the light intensity caused by the aging and the degradation of the first optical path can be more accurately detected, so that the structure of the processing target substrate can be investigated with higher precision. Further, since the first optical path and the second optical path can be switched by controlling the first reflection member configured to change the reflection direction of the light, it is possible to control the investigation of the structure of the processing target substrate as required.

Desirably, the analyzing process may include a first measurement process that measures an intensity of the light detected by the light detection unit through the first optical path passing process; a second measurement process that measures an intensity of the light detected by the light detection unit through the second optical path passing process; a calculation process that calculates a light intensity difference between an intensity of light detected by the light detection unit through the second optical path passing process at the time of starting a process and the intensity of the light measured in the second measurement process; a correction process that corrects the intensity of the light measured in the first measurement process based on the light intensity difference calculated in the calculation process; and a structure analyzing process that analyzes the structure of the processing target substrate based on the corrected intensity of the light. With this configuration, it may be possible to accurately detect the variation of the light intensity after starting the process when the aging and the degradation does not occur. Accordingly, the influence of the aging and the degradation of the first optical path can be excluded more securely. Thus, the structure of the processing target substrate can be investigated with higher precision.

In yet another example embodiment, a substrate processing apparatus includes a processing vessel configured to perform therein a plasma process on a processing target substrate; a mounting table provided in the processing vessel and configured to mount thereon the processing target substrate; a gas supply unit configured to supply a processing gas into the processing vessel; a plasma generating unit configured to generate plasma within the processing vessel; and a process monitoring device configured to investigate a structure of the processing target substrate by irradiating light to a surface of the processing target substrate and detecting reflection light from the processing target substrate. Further, the process monitoring device includes a light source unit configured to generate and output light; a light detection unit configured to detect an intensity of light inputted from an outside thereof; a first optical path configured to guide the light outputted from the light source unit to the processing target substrate and guide the reflection light from the processing target substrate to the light detection unit; a second optical path that is formed to have a light propagation characteristic equivalent to that of the first optical path and guides light outputted from the light source unit to the light detection unit without allowing the light to pass the processing target substrate; and a controller configured to correct intensity information of the light detected by the light detection unit via the first optical path based on intensity information of the light detected by the light detection unit via the second optical path, and configured to analyze a structure of the processing target substrate.

With this configuration, it may be possible to provide the substrate processing apparatus configured to investigate the structure of the processing target substrate with high precision while performing the plasma process on the processing target substrate.

### Effect of the Invention

In accordance with example embodiments, a variation of a light intensity caused by aging and degradation of a first optical path as a result of a continuous use can be accurately measured by measuring a variation of the intensity of the light detected by a light detection unit via a second optical path having a light propagation characteristic equivalent to that of the first optical path. As a result, based on variation information, it is possible to correct intensity information of the light detected by the light detection unit via the first optical path. That is, since an influence of the aging and the degradation of the first optical path can be excluded from the intensity information of the light detected by the light detection unit via the first optical path, it is possible to accurately measure an intensity of reflection light from a processing target substrate. Thus, a structure of the processing target substrate can be investigated with high precision.

### BRIEF DESCRIPTION OF THE DRAWINGS

FIG. 1 is a diagram schematically illustrating a process monitoring device in accordance with an example embodiment, and shows a state where light outputted from an optical monitor passes through a first optical path.

FIG. 2 is a diagram schematically illustrating the process monitoring device in accordance with the example embodiment, and shows a state where light outputted from the optical monitor passes through a second optical path.

FIG. 3 shows a flowchart of a process monitoring method in accordance with the example embodiment.

FIG. 4 is a graph showing a measurement result in a starting process in accordance with the example embodiment.

FIG. 5 shows a time chart of an ON/OFF signal of a light source unit of the optical monitor and a time chart of a control signal of a first mirror.

FIG. 6 provides a flowchart of an analyzing process in accordance with the example embodiment.

FIG. 7 is a graph showing a relationship between an ultraviolet intensity when an optical fiber cable is used continuously and a time after starting the measurement.

FIG. 8 is a schematic cross sectional view illustrating major components of a microwave plasma processing apparatus having the process monitoring device in accordance with the example embodiment, and shows a state where light passes through the first optical path in the process monitoring device.

FIG. 9 is a diagram schematically illustrating a process monitoring device in accordance with another example embodiment.

### DETAILED DESCRIPTION

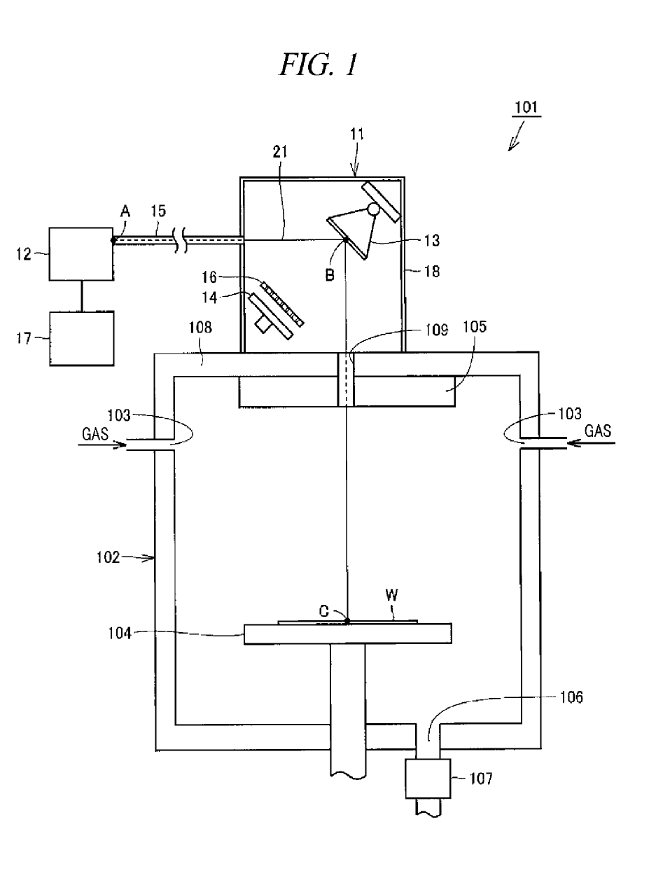

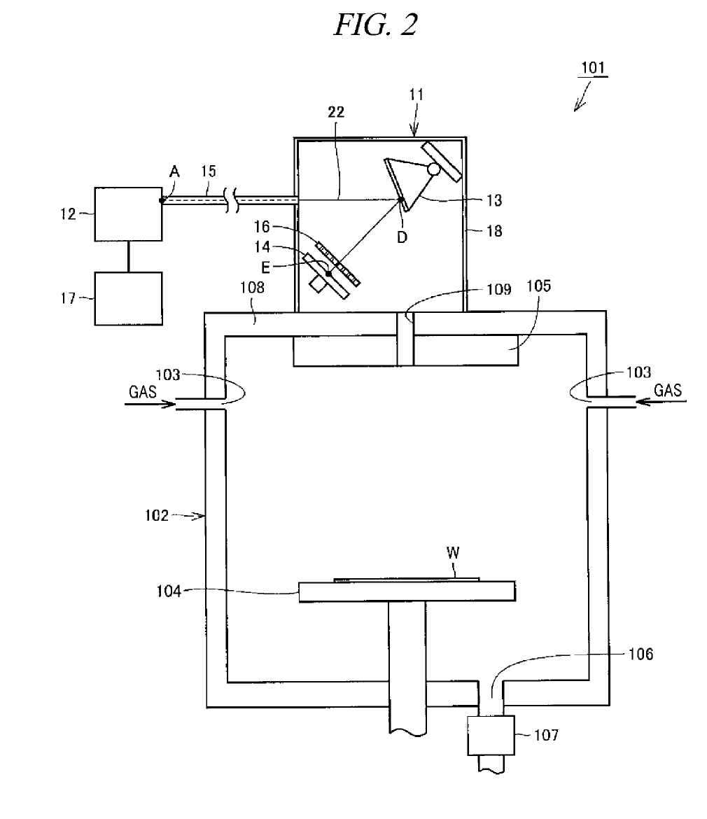

In the following, example embodiments will be described, and reference is made to the accompanying drawings, which form a part of the description. First, referring to FIG. 1 and FIG. 2, a configuration of a process monitoring device 11 in accordance with an example embodiment will be elaborated. FIG. 1 illustrates a state where light outputted from an optical monitor 12 passes through a first optical path 21. FIG. 2 illustrates a state where light outputted from the optical monitor 12 passes through a second optical path 22. Further, in the following description, a vertical direction accords to an up and down direction of a paper surface in FIG. 1. Further, in FIG. 1 and FIG. 2, for the sake of easy understanding, a part of constituent components are illustrated in the cross section and hatching is omitted.

Referring to FIG. 1 and FIG. 2, the process monitoring device 11 in accordance with the example embodiment is included in a plasma processing apparatus 101 and configured to measure, by an optical method, a thickness of a thin film formed on a surface of a wafer W, which serves as a processing target substrate.

The plasma processing apparatus 101 includes a processing vessel 102 configured to perform therein a plasma etching process on the wafer W; a gas supply unit 103 configured to supply an etching gas into the processing vessel 102; a circular plate-shaped supporting table 104 configured to support the wafer W from below; a plasma generating unit 105 configured to generate plasma within the processing vessel 102; an exhaust device 107 configured to exhaust a gas within the processing vessel 102 through an exhaust pipe 106 formed in a lower portion of the processing vessel 102; and a process controller (not shown) configured to control the plasma processing apparatus 101. The process controller may control overall operations of the plasma processing apparatus 101, including a gas flow rate in the plasma processing gas supply unit 103, a pressure within the processing vessel 102, and so forth.

The process monitoring device 11 in accordance with the example embodiment is configured to measure a thickness of a thin film formed on the surface of the wafer W by irradiating light to the surface of the wafer W and detecting reflection light therefrom while an etching process is being performed on the wafer W in the processing vessel 102.

The process monitoring device 11 includes the optical monitor 12, a first mirror 13, a second mirror 14 and an optical fiber cable 15. The optical monitor 12 has a light source unit (not shown) configured to generate and output the light; and a light detection unit (not shown) configured to detect an intensity of light introduced from the outside. The first mirror 13 is provided above the processing vessel 102 and configured to reflect the light outputted from the optical monitor 12. The second mirror 14 is provided to further reflect the light reflected by the first mirror 13. The optical fiber cable 15 is configured to guide the light outputted from the optical monitor 12 to the first mirror 13.

The optical monitor 12 includes the light source unit configured to generate light and to output the light through a light passing opening A. The light source unit configured to generate the light may be implemented by, but not limited to, a xenon lamp. In such a case, light having a spectrum covering from an ultraviolet range to an infrared range is generated and outputted through the light passing opening A.

Further, the optical monitor 12 includes the light detection unit configured to receive the incident light and measure an intensity of the incident light. When white light outputted from, e.g., a xenon lamp as a light source is received, the light detection unit separates the white light by the frequency bands thereof by an incorporated spectrometer and extracts a spectrum intensity corresponding to a frequency band suitable for investigating the structure of the wafer W. Then, the light intensity information obtained in this way is outputted to a controller 17. Operations of the controller 17 will be elaborated later.

The optical fiber cable 15 is a flexible cable having a certain length and is configured to transmit light. In general, the optical monitor 12 is placed at a position spaced apart from the processing vessel 102. Accordingly, the optical fiber cable 15 is used to guide the light from the optical monitor 12 up to a region above the processing vessel 102.

The first mirror 13 is controlled to change a reflection direction of the light introduced through the optical fiber cable 15 between a direction toward the wafer W placed in the processing vessel 102 and a direction toward the second mirror 14 disposed in a vicinity of the first mirror 13. The control and the operation of the first mirror 13 will be elaborated later.

The second mirror 14 is fastened in the vicinity of the first mirror 13 such that a surface thereof faces the first mirror 13. In the present example embodiment, a slit plate 16 configured to control a reflectance of reflection light from the second mirror 14 to the first mirror 13 to be constant is provided between the first mirror 13 and the second mirror 14. The first mirror 13, the second mirror 14 and the slit plate 16 are accommodated in a hollow case 18.

Now, optical paths in FIG. 1 and FIG. 2 will be described in detail. In the state shown in FIG. 1, the first mirror 13 is set to have a reflection angle where the first mirror 13 reflects the light irradiated through the optical fiber cable 15 toward the wafer W. The wafer W is mounted on the supporting table 104 in the processing vessel 102, and in the present example embodiment, the first mirror 13 is located at a position directly above the wafer W. Further, formed in an upper portion 108 of the processing vessel 102 and the plasma generating unit 105 is an optical passage 109 configured to allow the light reflected by the first mirror 13 to pass therethrough without being interfered. The optical passage 109 is made of, by way of example, but not limitation, quartz and has a seal member (not shown) configured to maintain an atmosphere within the processing vessel 102. Besides the quartz, the optical passage 109 may be made of any material as long as the material transmits light.

In the state shown in FIG. 1, after the light is outputted from the light passing opening A of the optical monitor 12, the light is introduced to the first mirror 13 through the optical fiber cable 15, and then, is reflected at a reflection point B on a surface of the first mirror 13. The reflection light is transmitted through the optical passage 109 and irradiated to the wafer W within the processing vessel 102, and then, reflected at a reflection point C on the surface of the wafer W. Since the wafer W is supported substantially in a horizontal manner, the light reflected from the wafer W would pass through the same optical path as stated above. That is, the reflection light reaches the first mirror 13, and then, is reflected at the reflection point B on the first mirror 13 and returned back into the light passing opening A through the optical fiber cable 15. Then, the reflection light from the wafer W is detected by the optical monitor 12.

In the state shown in FIG. 2, the first mirror 13 is set to have a reflection angle where the first mirror 13 reflects the light irradiated through the optical fiber cable 15 toward the second mirror 14. In this configuration, the light outputted from the light passing opening A of the optical monitor 12 is introduced to the first mirror 13 through the optical fiber cable 15 and reflected at a reflection point D on the first mirror 13. The reflection light is irradiated to the second mirror 14 after passing through the slit plate 16, and then, is reflected again at a reflection point E on the surface of the second mirror 14. The second mirror 14 is positioned such that the surface of the second mirror 14 is orthogonal to the incident light, so that the reflection light from the second mirror 14 would pass through the same optical path as stated above. That is, after reaching the first mirror 13, the reflection light would be reflected again at the reflection point D of the first mirror 13 and returned back into the light passing opening A through the optical fiber cable 15. In this way, the intensity of the light moving forward and backward through the optical fiber cable 15, which is shared in common with the first optical path 21 shown in FIG. 1, and returning back without passing the wafer W is detected by the optical monitor 12.

As stated above, in the process monitoring device 11 in accordance with the present example embodiment, the light outputted from the optical monitor 12 is guided by the optical fiber cable 15 and the first mirror 13. As a result, the first optical path 21 sequentially passing through the point A, the point B, the point C, the point B and the point A (point A→point B→point C→point B→point A) shown in FIG. 1 is formed. Further, the light outputted from the optical monitor 12 is also guided by the optical fiber cable 15, the first mirror 13 and the second mirror 14. As a result, the second optical path 22 sequentially passing through the point A, the point D, the point E, the point D and the point A (point A→point D→point E→point D→point A) shown in FIG. 2 is formed. The first optical path 21 and the second optical path 22 can be switched by controlling the reflection angle of the first mirror 13.

From the lights returning back to the optical monitor 12 via each of the first optical path 21 and the second optical path 22, only the frequency components suitable for measurement are extracted by the spectrometer, as mentioned above. Then, information regarding these light intensities is sent to the controller 17. The controller 17 calculates the thickness of the thin film formed on the wafer W based on a method as will be discussed below. The controller 17 is connected to the aforementioned process controller to communicate with each other.

Now, a process monitoring method for measuring a film thickness by using the process monitoring device 11 in accordance with the example embodiment will be discussed with reference to FIG. 1 to FIG. 7.

Referring to FIG. 1 to FIG. 7, the process monitoring method in accordance with the example embodiment is configured to measure, by using the process monitoring device 11, a thickness of a thin film formed on a wafer W by an etching process. This process monitoring method includes a starting process (block 31) for obtaining reference data required to measure a film thickness; a second optical path passing process (block 32) for guiding light outputted from the light source unit of the optical monitor 12 to the light detection unit of the optical monitor 12 via the second optical path 22; a first optical path passing process (block 33) for guiding light outputted from the light source unit of the optical monitor 12 to the light detection unit of the optical monitor 12 via the first optical path 21; an analyzing process (block 34) for calculating the thickness of the thin film formed on the wafer W based on intensity information of the lights obtained through the second optical path passing process (block 32) and the first optical path passing process (block 33); and a finishing process (block 35) for finishing the measurement of the film thickness based on previously stored data.

In order to measure the thickness of the thin film formed on the wafer W, at block 31 (starting process), reference data according to a correlation between intensity of reflection light from the wafer W detected by the optical monitor 12 and the film thickness are obtained. First, a reference wafer having thereon a thin film of a certain thickness is prepared, and the thickness of the reference wafer is measured by using an electron microscope or the like. Subsequently, light is irradiated to the reference wafer, and an ultraviolet intensity of reflection light from the reference wafer is measured. Then, while performing an etching process on the reference wafer, ultraviolet intensities of reflection lights are measured sequentially. After a preset time elapses, the etching process is finished, and a film thickness at that moment is measured by using the electron microscope or the like.

FIG. 4 shows a result of measuring the reference light intensities obtained at block 31. In FIG. 4, a horizontal axis represents an etching time and a vertical axis indicates an ultraviolet intensity of the reflection light. Further, a solid line 37 in FIG. 4 indicates actually measured intensity values, while a dashed dotted line 38 indicates mean values thereof. In this reference light intensity measurement, an initial thickness of the thin film formed on the reference wafer is about 12.4 nm and a relative ultraviolet intensity is about 1300 (Point 36 in FIG. 4).

As shown in FIG. 4, as the etching process is performed on the wafer and the thickness of the thin film is decreased, the light intensity is increased. This phenomenon will be briefly explained. When light is irradiated to a wafer having thereon a thin film of a certain thickness, there are generated reflection light from the surface of the thin film and reflection light from the surface of the wafer after passing through the thin film. Since these reflection lights interfere with each other while being overlapped, the light intensity of each reflection light may be affected. Such a light interference may vary depending on a thickness of the thin film. That is, the intensity of the reflection light and the thickness of the thin film formed on the wafer are in correlation as shown in FIG. 4. Thus, by measuring the light intensity, the film thickness can be found quantitatively.

As depicted in FIG. 4, as a result of performing the etching process for a certain time, the film thickness is about 1.9 nm, and the relative ultraviolet intensity measured at that moment is about 1400 (Point 39 in FIG. 4). That is, when the film thickness is changed by 1 nm, a variation δL of the light intensity is calculated as follows:

δL=(1400−1300)/(12.4−1.9)=9.5 [Relative intensity/nm]

This variation δL is reference data indicating the correlation between the light intensity and the film thickness. Further, this variation δL is required to calculate the film thickness based on the light intensity.

After block 31, an etching process is performed on a wafer W to be actually processed. While performing the etching process on the wafer W, the second optical path passing process 32, the first optical path passing process 33 and the analyzing process 34, which will be described later, are performed. In an actual production process, these processes are performed on a multiple number of wafers W continuously. In such a case, the processes of etching the reference wafer and obtaining the reference data δL at block 31 need to be performed at least one time when starting the process. That is, once the reference data are obtained when starting the process, the reference data can also be used in the subsequence processes. Furthermore, when performing same processes, it may be possible to share the reference data.

Thereafter, at block 32 (second optical path passing process), the reflection angle of the first mirror 13 is set as depicted in FIG. 2. In this state, the light source unit of the optical monitor 12 outputs light. The light outputted from the light passing opening A is guided by the optical fiber cable 15, the first mirror 13 and the second mirror 14 to pass through the second optical path 22 via the point A, the point D, the point E, the point D and the point A (point A→point D→point E→point D→point A) as shown in FIG. 2, and then, is inputted to the light detection unit of the optical monitor 12.

Then, at block 33 (first optical path passing process), the reflection angle of the first mirror 13 is set as depicted in FIG. 1. In this state, the light source unit of the optical monitor 12 outputs light again. The light outputted from the light passing opening A is guided by the optical fiber cable 15 and the first mirror 13 to pass through the first optical path 21 via the point A, the point B, the point C, the point B and the point A (point A→point B→point C→point B→point A) as shown in FIG. 1, and then, is inputted to the light detection unit of the optical monitor 12.

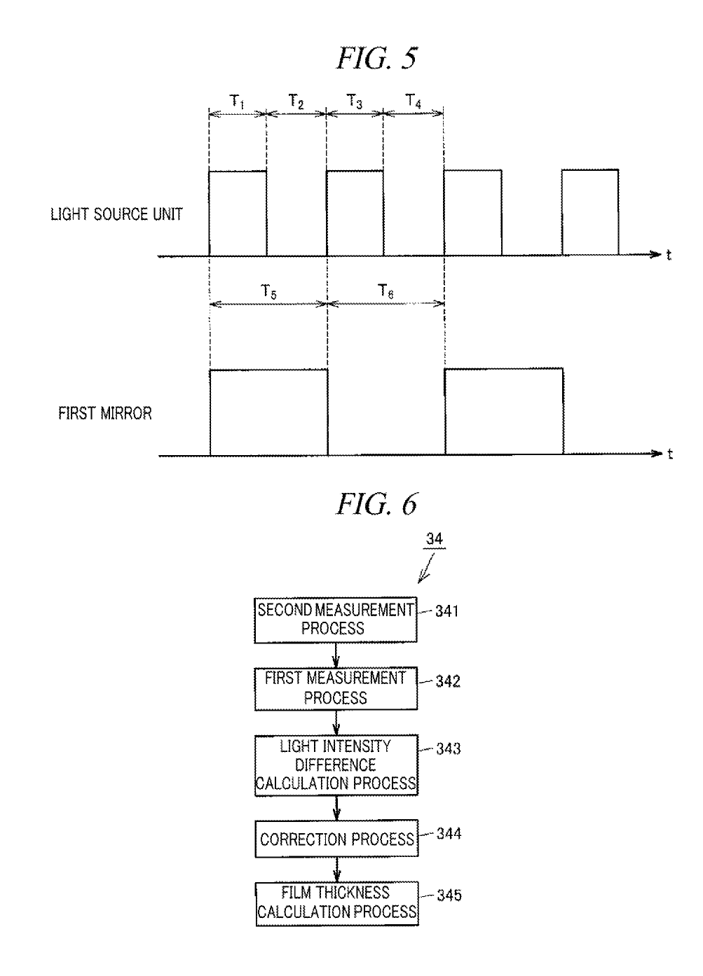

FIG. 5 illustrates a time chart of an ON/OFF signal of the light source unit of the optical monitor 12 and a time chart of a control signal of the first mirror 13. For periods T₁ and T₃ during which the light source unit is ON, light is outputted from the light source unit. For a period T₅ during which the control signal of the first mirror 13 is ON, the first mirror 13 is controlled to have the reflection angle as depicted in FIG. 2. For a period T₆ during which the control signal of the first mirror 13 is OFF, the first mirror 13 is controlled to have the reflection angle as depicted in FIG. 1. That is, the first mirror 13 is a direction-variable mirror, and the reflection angle of the first mirror 13 can be controlled electrically. By way of example, but not limitation, a galvano mirror may be used as such a mirror.

The second optical path passing process (block 32) is carried out during the period T₅. That is, light is outputted from the light source unit and a light intensity is measured during the period T₁. Then, the light is not outputted during a period T₂. The first optical path passing process (block 33) is carried out during the period T₆. That is, light is outputted from the light source unit and a light intensity is measured during the period T₃. Then, the light is not outputted during a period T₄. As an example cycle of the ON/OFF signal shown in FIG. 5, T₁=T₂=T₃=T₄ may be set to be in a range from, but not limited to, about 50 msec to about 100 msec. That is, the reflection angle of the first mirror 13 may be changed at a frequency of, but not limited to, about 2.5 Hz to about 5 Hz. In this way, the process monitoring method in accordance with the present example embodiment can be controlled electrically by the control signal shown in FIG. 5.

Then, at block 34 (analyzing process), intensities of lights passing through the second optical path 22 and the first optical path 21 are measured, respectively, and based on the measured intensity information, a thickness of a thin film formed on the wafer W is calculated. FIG. 6 provides a flowchart of 34 of the analyzing process in accordance with the example embodiment. The analyzing process 34 includes a second measurement process (block 341) for measuring an intensity of light detected by the light detection unit of the optical monitor 12 after block 32; a first measurement process (block 342) for measuring an intensity of light detected by the light detection unit after block 33; a light intensity difference calculation process (block 343) for calculating a difference between the light intensity measured at block 341 and the data measured at the time of starting the film thickness measurement process; a correction process (block 344) for correcting the light intensity measured at block 342 based on the information of the light intensity difference calculated at block 343; and a film thickness calculation process (block 345) for calculating the film thickness of the wafer W based on the corrected light intensity information.

In the present example embodiment, a film thickness may be calculated by detecting a light intensity of an ultraviolet component among frequency components of the light detected by the light detection unit. That is, at block 341 and block 342, an ultraviolet intensity of the light inputted to the optical monitor 12 is measured by using the spectrometer.

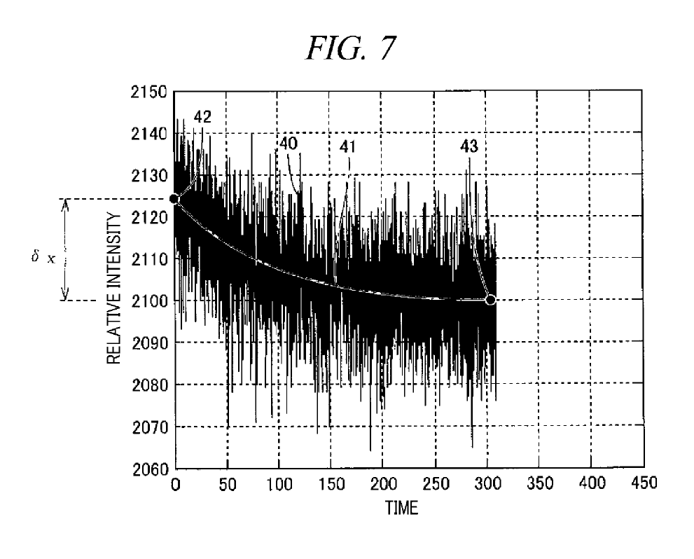

Herein, as reference data, FIG. 7 provides a graph showing a decrease of the ultraviolet intensity as a result of using the optical fiber cable 15 continuously. FIG. 7 provides the graph showing a relationship between a time that has passed after starting the measurement and an ultraviolet intensity of the reflection light from a normal state wafer, which is not yet etched, after the light is irradiated through the optical fiber cable 15. In FIG. 7, a horizontal axis represents the time and a vertical axis represents the ultraviolet intensity of the light. Further, a solid line 40 represents an actual measurement value of the ultraviolet intensity and a dashed dotted line 41 represents mean values thereof. Further, the measurement result shown in FIG. 7 is obtained under processing conditions in which an ultraviolet ray having a wavelength of, e.g., about 200 nm is irradiated to a wafer having a SiO₂ film formed on bare silicon in an atmosphere of N₂ at a pressure of, e.g., about 100 mT. A sampling time is about 0.1 second.

As shown in FIG. 7, if the ultraviolet intensity is continuously measured in the above measurement conditions, the ultraviolet intensity tends to be gradually decreased over time. In this measurement, since the ultraviolet intensity of the reflection light from the normal state wafer, which is not yet etched, is measured, it is common that the measured ultraviolet intensity has a constant value. However, actually, since the optical fiber cable 15 is continuously used, the ultraviolet intensity is decreased as time goes on. This may be caused by the aforementioned phenomenon that the optical fiber cable is damaged and degraded by the ultraviolet component of the light and the ultraviolet component of the light passing through the optical fiber cable 15 is reduced accordingly.

As shown in FIG. 7, a relative intensity measured at the time of starting the ultraviolet intensity measurement process is about 2125 (Point 42 in FIG. 7). As the measurement process is continued, the relative intensity is decreased and reaches about 2100 after a lapse of a certain time. That is, since the optical fiber cable 15 is damaged and degraded as time goes on, the relative ultraviolet intensity is decreased by about 25 (δx) regardless of the decrease of the film thickness by an etching process. If the decrease (δx=25) of the relative intensity is converted into a variation St of the thin film thickness based on the variation δL, the variation δt can be expressed as follows.

δt=25/9.5≈2.63 nm

As can be seen clearly from this result, if the optical fiber cable 15 is continuously used in the film thickness measurement process, the measurement result includes an error corresponding to the variation δt. Thus, it may become difficult to accurately measure the film thickness.

Therefore, in accordance with the present example embodiment, the analyzing process (block 34) includes the light intensity difference calculation process (block 343) for calculating the decrease δx and the correction process (block 344) for correcting the light intensity information based on the decrease δx. The light intensity difference calculation process (block 343) and the correction process (block 344) are performed before calculating the film thickness.

At block 343, the decrease δx is calculated by comparing the information of the light intensity measured at block 341 with the information of the light intensity measured at block 341 at the time of starting the process. That is, referring to FIG. 7, the difference δx between the intensity (ultraviolet intensity measured at block 341 at the time of starting the process) indicated as the point 42 in FIG. 7 and the intensity (ultraviolet intensity currently measured at block 341) indicated as the point 43 in FIG. 7 is calculated. Further, at block 344, correction is made by adding the decrease δx to the intensity of the reflection light from wafer W measured at block 342. By performing such correction, an influence of degradation of the optical fiber cable 15 as time goes on can be excluded from the light intensity information obtained at block 342.

After block 344, at block 345 (film thickness calculation process), the thickness of the thin film formed on the wafer W is calculated based on the corrected light intensity information. The film thickness is calculated by using the variation δL obtained at block 31. Hereinafter, a specific example of the calculation of the film thickness at block 345 will be described.

A thickness of a thin film formed on the wafer W before starting the process is represented by t₀ and a light intensity measured at block 342 right after the process is started is represented by L₀. Further, a light intensity measured at block 342 as a result of an etching process is represented by Lₓ and a decrease obtained at block 343 is represented by δx. In this case, at block 344, the light intensity Lₓ measured at block 342 is corrected to Lₓ+δx. Based on the corrected light intensity information, a thickness tₑ decreased by the etching process after starting the process is calculated by the following equation.

tₑ=(Lₓ+δx−L₀)/9.5

Therefore, a film thickness tᵣ of the thin film remaining on the wafer W at that moment is calculated by the following equation.

tᵣ=t₀−tₑ=t₀−(Lₓ+δx−L₀)/9.5

In this way, at block 345, the film thickness t, of the thin film remaining on the wafer W can be calculated quantitatively based on the light intensity information.

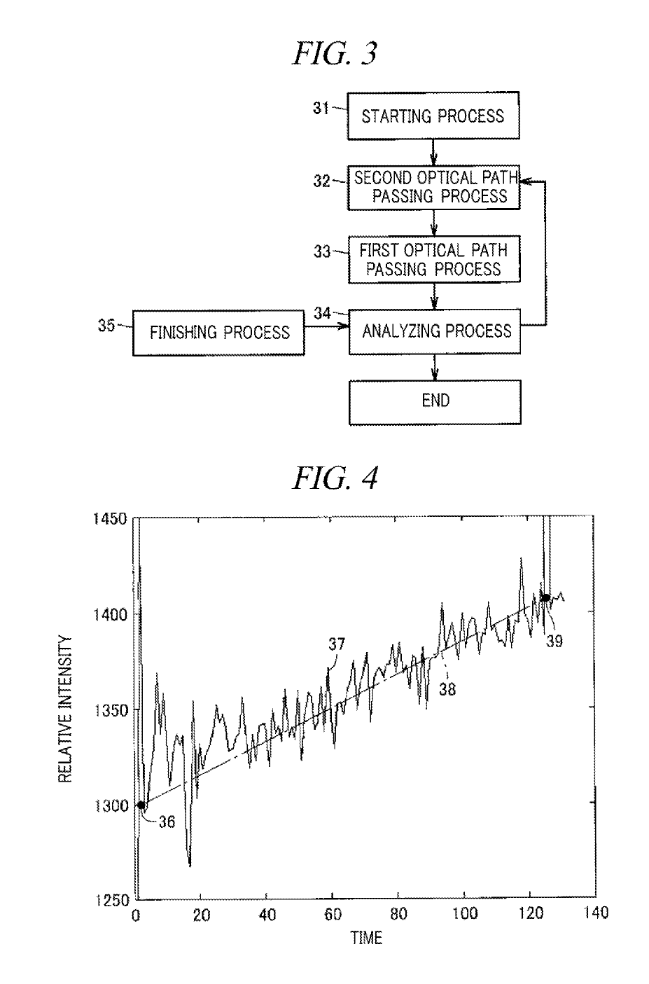

After the film thickness is calculated as described above at block 34, the process returns back to block 32. Then, an etching process is performed on the wafer W and the film thicknesses are calculated sequentially. When the thickness of the thin film formed on the wafer W reaches a preset thickness, the process is finished at block 35 (finishing process). That is, data regarding the required film thickness after the etching process are recorded in advance, and when the thickness tᵣ of the remaining thin film calculated at block 34 reaches the required film thickness, the cycle shown in FIG. 3 is finished at block 35.

In the present example embodiment, even if the process monitoring device 11 is continuously used, it is possible to calculate a film thickness with higher precision. Details thereof will be explained below.

As shown in FIG. 7, if the optical fiber cable 15 is used continuously, since the optical fiber cable may be damaged and degraded by an ultraviolet component of light as time goes on, the ultraviolet component may be gradually reduced. As described above, this may be an obstacle to accurately measure a film thickness.

In the process monitoring method in accordance with the present example embodiment, before performing the first optical path passing process (block 33) for obtaining light intensity information required for calculating a film thickness, the second optical path passing process (block 32) for obtaining the decrease δx of the light intensity caused by the aging and the degradation of the optical fiber cable is carried out. Then, at block 34, the light intensity information for the calculation of the film thickness is frequently corrected by the decrease δx. Further, the aging and the degradation of the optical fiber cable, which are caused by the ultraviolet component, progress every several minutes. In this regard, in the present example embodiment, as shown in FIG. 5, the measurement for obtaining the light intensity information required for correction and the measurement for obtaining the light intensity information required for calculation of the film thickness are performed alternately at an interval of, but not limited to, from about 100 msec to about 200 msec. Therefore, effects of the aging and the degradation of the optical fiber cable in the two measurements can be disregarded.

Further, the first optical path 21 and the second optical path 22 share the optical fiber cable 15. A path from the point B to the point C in the first optical path 21 and a path from the point D to the point E in the second optical path 22 neither affect the characteristics of the light passing therethrough nor cause a decrease of the ultraviolet component. Therefore, it may be regarded that the first optical path 21 and the second optical path 22 have the same light propagation characteristics, such as a decrease of the ultraviolet component due to the aging and the degradation of the optical fiber cable.

That is, in accordance with the present example embodiment, a variation of the light intensity caused by the aging and the degradation of the optical fiber cable 15 in the first optical path 21 can be detected accurately by measuring an intensity variation of the light passing through the second optical path 22. Thus, it is possible to correct the light intensity information required for calculation of the film thickness obtained at block 33 to offset the variation. That is, the influence of the aging and the degradation of the optical fiber cable 15 can be excluded from the light intensity information for calculating the film thickness. Therefore, it may become possible to measure a thickness of a thin film formed on the wafer W accurately.

Further, in accordance with the present example embodiment, the first optical path 21 and the second optical path 22 can be selected by electrically controlling the first mirror 13 configured to change the reflection angle thereof. That is, it is possible to selectively control the main measurement and the measurement for correction as required. Thus, the film thickness of the wafer W can be measured in a securely controlled manner. Since the switching between the first optical path 21 and the second optical path 22 can be achieved by, but not limited to, the galvano mirror as a general-purpose member, the process monitoring device 11 can be more easily structured.

The process monitoring device 11 in accordance with the present example embodiment can be applied to any kinds of plasma processing apparatuses such as a microwave plasma processing apparatus using a microwave as a plasma source, a parallel plate type plasma processing apparatus, an ICP (Inductively-Coupled Plasma) plasma processing apparatus, or an ECR (Electron Cyclotron Resonance) plasma processing apparatus. Hereinafter, as an application example, there will be explained an example embodiment where the process monitoring device 11 is applied to a microwave plasma processing apparatus using a slot antenna.

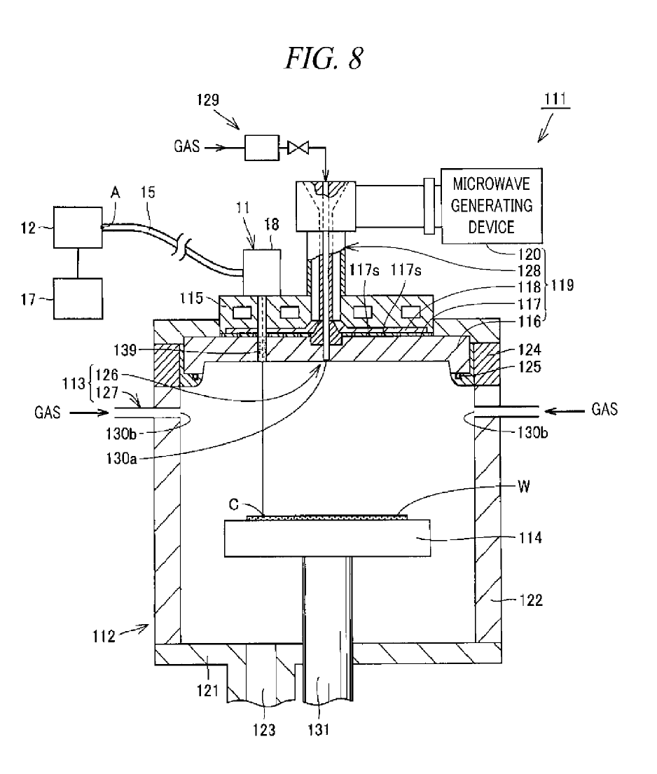

FIG. 8 is a schematic cross sectional view illustrating major components of a microwave plasma processing apparatus 111 having the process monitoring device 11. FIG. 8 shows a status where the light passes through the first optical path by the process monitoring device 11.

Referring to FIG. 8, the plasma processing apparatus 111 includes a processing vessel 112 configured to perform therein a plasma process on a wafer W; a plasma processing gas supply unit 113 configured to supply a plasma processing gas into the processing vessel 112; a circular plate-shaped supporting table 114 configured to support the wafer W from below; a plasma generating device 119 configured to generate plasma within the processing vessel 112; and a process controller (not illustrated) configured to control the plasma processing apparatus 111. The process controller controls the overall operations of the plasma processing apparatus 111 such as a gas flow rate in the plasma processing gas supply unit 113, a pressure within the processing vessel 112, and so forth. The process monitoring device is connected to this process controller via the controller 17 to communicate with the process controller.

The processing vessel 112 includes a bottom 121 positioned under the supporting table 114 and a sidewall 122 extended upwardly from a periphery of the bottom 121. The sidewall 122 has a substantially cylindrical shape. An exhaust pipe 123 through which a gas is exhausted is provided in the bottom 121 of the processing vessel 112 to pass through a part thereof. The processing vessel 112 has a top opening, and an inside of the processing vessel 112 is airtightly sealed by an annular member 124 provided at an upper portion of the processing vessel 112, a dielectric window 116 to be described later, and an O-ring 125 as a sealing member provided between the dielectric window 116 and the annular member 124.

The plasma processing gas supply unit 113 includes a first plasma processing gas supply unit 126 configured to supply a gas toward a central portion of wafer W; and a second plasma processing gas supply unit 127 configured to supply a gas from a peripheral side of the wafer W. The first plasma processing gas supply unit 126 supplies a gas into the processing vessel 112 through a gas supply hole 130a formed at a central portion of the dielectric window 116 in a diametric direction thereof. The first plasma processing gas supply unit 126 is configured to supply a plasma processing gas while a flow rate thereof is controlled by a gas supply system 129 connected to the first plasma processing gas supply unit 126. The second plasma processing gas supply unit 127 is configured to supply a plasma processing gas into the processing vessel 112 through multiple gas supply holes 130b formed at a part of an upper portion of the sidewall 122. The multiple gas supply holes 130b are substantially equi-spaced along the periphery of the sidewall 122.

The supporting table 114 is configured to hold thereon the wafer W by an electrostatic chuck (not illustrated). The electrostatic chuck may be omitted. The supporting table 114 can be set to a required temperature by a temperature controller (not illustrated) provided therein. The supporting table 114 is supported on a cylinder-shaped insulating support 131 vertically extended from below the bottom 121. The exhaust pipe 123 is provided to pass through a part of the bottom 121 of the processing vessel 112. A downstream side of the exhaust pipe 123 is connected to an exhaust device (not illustrated). The exhaust device includes a vacuum pump such as a turbo molecular pump or the like. The inside of the processing vessel 112 can be depressurized to a certain pressure level by the exhaust device.

The plasma generating device 119 includes a microwave generating device 120, the dielectric window 116, a slot antenna plate 117, a dielectric member 118 and a waveguide 128. The microwave generating device 120 is provided at an outside of the processing vessel 112 and configured to generate a microwave for plasma excitation. The dielectric window 116 is provided to face the supporting table 114 and configured to introduce the microwave generated by the microwave generating device 120 into processing vessel 112. The slot antenna plate 117 is provided above the dielectric window 116 and configured to radiate the microwave to the dielectric window 116. The dielectric member 118 is provided above the slot antenna plate 117 and configured to propagate the introduced microwave along a diametric direction thereof. The waveguide 128 is configured to introduce the microwave transmitted from the microwave generating device 120 to the dielectric member 118. Above the dielectric member 118, a cover plate 115 is provided to cover the dielectric member 118 from above.

The dielectric window 116 is made of a substantially circular plate-shaped dielectric material and placed on the annular member 124 to close the top opening of the processing vessel 112. As a specific example, but not limitation, the dielectric window 116 may be made of quartz, alumina, or the like.

The slot antenna plate 117 is a circular and thin plate member. The slot antenna plate 117 has multiple slots 117s. The microwave introduced from the dielectric member 118 to the slot antenna plate 117 is radiated toward the dielectric window 116 through these slots 117s.

The dielectric member 118 is a circular and thin plate member, and is arranged concentrically with the dielectric window 116. Further, the dielectric member 118 is positioned such that a bottom surface of the dielectric member 118 faces a top surface of the dielectric window 116. The dielectric member 118 propagates the microwave introduced from the waveguide 128 outward in a radial direction. Thus, the microwave is introduced to the slot antenna plate 117.

The waveguide 128 is made of a conductor having a circular cross section or a rectangular cross section, and one end of the waveguide 128 is connected to the microwave generating device 120 while the other end thereof is connected to a central portion of the slot antenna plate 117.

The microwave supplied from the microwave generating device 120 propagates within the waveguide 128 and is introduced into the dielectric member 118. Then, the microwave propagates within the dielectric member 118 outward in the radial direction, and then, is radiated to the dielectric window 116 through the multiple slots 117s formed in the slot antenna plate 117. The microwave introduced into the dielectric window 116 forms an electric field within the dielectric window 116. Then, the microwave transmitted through the dielectric window 116 forms an electric field directly below the dielectric window 116. Plasma is generated by exciting a plasma processing gas within the processing vessel 112.

In the present example embodiment, the process monitoring device 11 is provided at a position a slightly deviated outward from a central portion of the cover plate 115. The optical passage 139 is formed through the dielectric window 116, the slot antenna plate 117, the dielectric member 118 and the cover plate 115 in a vertical direction to be located directly under a case 18 of the process monitoring device 11. A light transmission member configured to transmit light is filled in the optical passage 139 while maintaining a depressurized state within the processing vessel 112. The light transmission member is made of, by way of example, but not limitation, quartz that does not affect the characteristics of the light passing therethrough. Further, the light transmission member may be formed as one body with the dielectric window 116. Furthermore, if a film thickness of a wafer W is measured by using the ultraviolet ray as in the above-described example embodiment, synthetic quartz having a high transmittance to an electromagnetic wave of a short wavelength may be applied to the optical passage 139. In such a case, when the light passes through the optical passage 139, it may be possible to effectively suppress a decrease of an ultraviolet intensity.

As stated above, by providing the process monitoring device 11 in accordance with the present example embodiment in the plasma processing apparatus 111 as depicted in FIG. 8, a film thickness of the wafer W can be monitored appropriately while a plasma process is performed to the wafer W within the processing vessel 112.

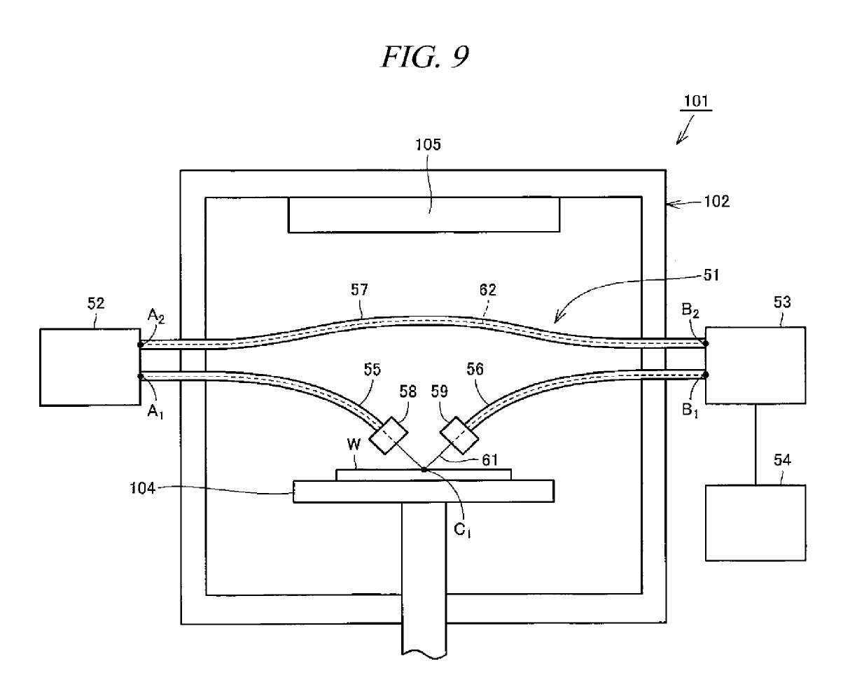

Hereinafter, a process monitoring device 51 in accordance with another example embodiment will be explained with reference to FIG. 9. Components similar or corresponding to those of the above-described example embodiment will be assigned similar reference numerals, and detailed descriptions thereof will be omitted. Further, for the sake of easy understanding, a part of the components are illustrated in cross section and hatching is omitted in FIG. 9.

Referring to FIG. 9, the process monitoring device 51 in accordance with another example embodiment is configured to measure a film thickness of a wafer W and is provided in a plasma processing apparatus 101. The process monitoring device 51 includes a light source unit 52 configured to generate and output light to an outside; a light detection unit 53 configured to detect an intensity of incident light introduced from the outside; and a controller 54 connected to the light detection unit 53 and configured to calculate a thickness of a thin film formed on the wafer W based on the intensity information of the incident light to the light detection unit 53.

Herein, the process monitoring device 51 in accordance with the present example embodiment includes a first optical fiber cable 55 configured to guide light outputted from a first light passing opening A₁ of the light source unit 52 to the wafer W; a second optical fiber cable 56 configured to guide reflection light from the wafer W to a first light passing opening B₁ of the light detection unit 53; and a third optical fiber cable 57 configured to guide light outputted from a second light passing opening A₂ of the light source unit 52 to a second light passing opening B₂ of the light detection unit 53 without allowing the light to pass the wafer W.

At an end of the first optical fiber cable 55 on a side of the wafer W, there is provided a light emitting unit 58 configured to irradiate the light transmitted through the optical fiber cable toward the wafer W. Further, at an end of the second optical fiber cable 56 on a side of the wafer W, there is provided a light receiving unit 59 configured to receive the reflection light from the wafer W and to transmit the reflection light to the second optical fiber cable 56.

In the present example embodiment, as depicted in FIG. 9, a first optical path 61 is formed by the first optical fiber cable 55, the light emitting unit 58, the light receiving unit 59, and the second optical fiber cable 56. To be more specific, the light outputted from the first light passing opening A₁ of the light source unit 52 is irradiated to the wafer W from the light emitting unit 58 after passing through the first optical fiber cable 55, and then, is reflected from a reflection point C₁ on a surface of the wafer W. The reflection light is received from the light receiving unit 59, and then, is inputted to the first light passing opening B₁ of the light detection unit 53 through the second optical fiber cable 56. As described, the light outputted from the light source unit 52 is guided to the point A₁→the point C₁→the point B₁, so that the first optical path 61 is formed.

A second optical path 62 is formed by the third optical fiber cable 57. That is, the light outputted from the light source unit 52 is guided to reach the point A₂ and the point B₂ (point A₂→point B₂) through the third optical fiber cable 57 without allowing the light to pass the wafer W.

Herein, the first to third optical fiber cables 55, 56, and 57 may be selected such that the first optical path 61 and the second optical path 62 have the same light propagation characteristics. That is, as a specific example, a length of the third optical fiber cable 57 may be set to be equal to the sum of lengths of the first optical fiber cable 55 and the second optical fiber cable 56. Further, the first to third optical fiber cables 55, 56, and 57 are set to be of the same kind. With this configuration, the light propagation characteristics of the first optical path 61 and the second optical path 62 can be made identical. That is, degrees of aging and degradation caused by the ultraviolet component in the first optical path 61 and the second optical path 62 may be identical to each other.

The controller 54 is configured to calculate a thickness of a thin film formed on the wafer W based on intensity information of lights inputted to the light detection unit 53.

Hereinafter, an operation of the process monitoring device 51 in accordance with this another example embodiment will be explained. The process monitoring device 51 is operated according to the flowcharts of FIG. 3 and FIG. 6 in the same manner as described in the aforementioned example embodiment. Therefore, detailed descriptions of parts similar to those of the aforementioned example embodiment will be omitted.

At block 31 (starting process), reference data according to a correlation between a light intensity and a film thickness are obtained. That is, there are obtained data regarding a variation δL of a light intensity when a film thickness is changed by about 1 nm. Then, at block 32 (second optical path passing process), light outputted from the light source unit 52 is guided to pass through the second optical path 62 via the point A₂ and the point B₂ (point A₂→point B₂), and reaches the light detection unit 53. Thereafter, at block 33 (first optical path passing process), light outputted from the light source unit 52 is guided to pass through the first optical path 61 via the point A₁, the point C₁ and the point B₁ (point A₁→point C₁→point B₁), and reaches the light detection unit 53. Then, at block 34 (analyzing process), intensities of the lights respectively passing through the second optical path 62 and the first optical path 61 are measured, and based on this intensity information, a thickness of a thin film formed on the wafer W is calculated.

At block 34, an intensity of the light passing through the second optical path 62 is measured at block 341. Then, an intensity of the light passing through the first optical path 61 is measured at block 342. Thereafter, at block 343 (light intensity difference calculation process), a decrease δx is calculated by comparing the light intensity information measured at block 341 with information of a light intensity measured at the time of starting the process. Then, at block 344 (correction process), correction is made by adding the decrease δx to the light intensity measured at block 342. Thereafter, at block 345 (film thickness calculation process), based on the corrected light intensity information and the reference data (variation δL), a thickness of the thin film formed on wafer W is calculated.

Herein, in accordance with the present example embodiment, as described above, since the first optical path 61 and the second optical path 62 are formed to have the same light propagation characteristics, decreases in ultraviolet intensities of the lights in the first optical path 61 and the second optical path 62 may be equivalent while the process is being performed. Therefore, by correcting the light intensity information for calculation of the film thickness obtained at block 33 based on the light intensity information for correction obtained at block 32, an influence of the aging and the degradation of an optical fiber cable can be excluded from the light intensity information for calculating the film thickness. Accordingly, it may become possible to accurately measure the thickness of the thin film formed on wafer W.

Further, in the above-described example embodiments, there have been explained a device and a method for calculating a thickness of a thin film formed on a wafer as an example. However, the technical conception of the present disclosure lies in that by correcting intensity information (information for main measurement) of light passing through a first path via a target object to be measured based on intensity information (information for correction) of light passing through a second path having the same characteristics as those of the first path and not passing the target object, the influence, which is caused by the paths, upon the intensity information for main measurement is excluded. Therefore, besides being used to measure a thickness of a thin film, the technical conception may have a wide range of applications as long as it is used to investigate structural characteristics (dimension, surface shape, material composition, or the like) of the target object by irradiating light to the target object.

The term “light propagation characteristic” used in the above description includes all kinds of characteristics that may affect light-related parameters such as intensity, wavelength, phase, polarization, and distortion of light. Therefore, the technical range of the present disclosure may not be limited to investigating a structure of a target object based on the “intensity” of light as shown in the above example embodiments but may also include investigating a structure of a target object based on other light-related parameters such as wavelength, phase, polarization, and distortion.

Further, the above example embodiments have been explained for the case of acquiring the reference data δL by using the method as shown in FIG. 4 and investigating a film thickness quantitatively based on the reference data δL and the obtained light intensity information. However, the example embodiments may not be limited thereto. That is, a wafer structure can be investigated by using any method as long as the wafer structure is investigated by using light intensity information as one of parameters.

Furthermore, the above example embodiments have been explained for the case that each of an optical path for main measurement that passes a target object and an optical path for correction that does not pass the target object is formed of a single path. However, the example embodiments may not be limited thereto, and each of the optical path for main measurement and the optical path for correction may be formed of multiple paths.

Moreover, the above example embodiments have been described for the case that an optical path is formed by an optical fiber cable and a mirror. However, the example embodiments may not be limited thereto, and optical paths may be formed by any member and any method as long as they can transmit light, and an optical path for main measurement and an optical path for correction have the same light propagation characteristics.

As a characteristic of an optical fiber cable in the above-described example embodiments, it is apparent that if a continuous use of the optical fiber cable is stopped temporarily and an ultraviolet intensity is measured again, an ultraviolet intensity value increases. That is, the optical fiber cable can be recovered from the aging and the degradation by stopping the continuous use thereof. Further, it is also apparent that an ultraviolet intensity value varies depending on a processing pressure or a processing gas atmosphere. Thus, an increase or a decrease of the ultraviolet intensity may be caused by various factors, and may vary from moment to moment. Therefore, when measuring a film thickness of a wafer, as described in the example embodiments, it may be effective to alternatively perform the measurement for correction and the measurement for calculation of the film thickness and perform the correction of the ultraviolet intensity sequentially.

Further, in the above-described example embodiments, a device and a method for measuring a film thickness in an etching process have been described. However, the example embodiments may not be limited thereto and may be applied to investigating a structure in various other semiconductor manufacturing processes including a film forming process such as CVD, a sputtering process, etc.

Furthermore, the above example embodiments have been described for the case that a semiconductor wafer is used as a processing target substrate on which a process is performed. However, the example embodiments may not be limited thereto. By way of non-limiting example, the embodiments may be applied to processing various kinds of substrates such as a glass substrate for a flat panel display, a flexible plastic substrate, etc.

Moreover, in the above-described embodiments, a xenon lamp configured to generate white light is used as a light source, but the embodiments may not be limited thereto. In order to investigate a finer structure more effectively, a light source configured to generate ultraviolet light of about 300 nm or less may be employed and a structure of a target object may be investigated by using only an ultraviolet ray. Besides, it may be also possible to use an electromagnetic wave having a certain wavelength.

In FIG. 1, FIG. 2, FIG. 8, and FIG. 9, for the sake of easy understanding, optical paths are indicated by lines. However, it is common that light passing through an optical path is actually irradiated as convergent light (beams) having a certain cross sectional area.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

### INDUSTRIAL APPLICABILITY

The example embodiments provide a process monitoring device and a process monitoring method capable of investigating a wafer structure by using an optical method with higher precision and may be advantageously applied to a semiconductor manufacturing field.

### EXPLANATION OF CODES

11, 51: Process monitoring device
12: Optical Monitor
13: First mirror
14: Second mirror
15, 55, 56, 56: Optical fiber cable
16: Slit plate
17, 54: Controller
18: Case
21, 61: First optical path
22, 62: Second optical path
32, 32, 33, 34, 341, 342, 343, 344, 345, 35: Block
36, 39, 42, 43: Point
37, 38, 40, 41: Line
52: Light source unit
53: Light detection unit
58: Light emitting unit
59: Light receiving unit
101, 111: Plasma processing apparatus
102, 112: Processing vessel
103, 113, 126, 127: Gas supply unit
104, 114: Supporting table
105: Plasma generating unit
106, 123: Exhaust pipe
107: Exhaust device
108: Upper portion
109, 139: Optical passage
115: Cover plate
116: Dielectric window
117: Slot antenna plate
117s: Slot
118: Dielectric member
119: Plasma generating device
120: Microwave generating device
121: Bottom
122: Sidewall
124: Annular member
125: O-ring
128: Waveguide
129: Gas supply system
130a, 130b: Gas supply hole

We claim:

1. A process monitoring device of investigating a structure of a processing target substrate by irradiating light to a surface of the processing target substrate provided within a processing vessel of a substrate processing apparatus and detecting reflection light from the processing target substrate, the process monitoring device comprising:
a light source unit configured to generate and output light;
a light detection unit configured to detect an intensity of light inputted from an outside thereof;
a first optical path configured to guide the light outputted from the light source unit to the processing target substrate and guide the reflection light from the processing target substrate to the light detection unit;
a second optical path that is formed to have a light propagation characteristic equivalent to that of the first optical path and is configured to guide the light outputted from the light source unit to the light detection unit without allowing the light to pass the processing target substrate; and
a controller configured to correct intensity information of the light detected by the light detection unit via the first optical path based on intensity information of the light detected by the light detection unit via the second optical path, and configured to analyze the structure of the processing target substrate.

2. The process monitoring device of claim 1,
wherein each of the first optical path and the second optical path includes an optical fiber cable, and the optical fiber cables are made of the same material and have the same total length.

3. The process monitoring device of claim 1, further comprising:
a first mirror disposed to reflect the light outputted from the light source unit and configured to change a reflection direction of the light; and
a second mirror disposed to further reflect the light reflected by the first mirror,
wherein the first mirror is configured to periodically change the reflection direction of the light between a reflection direction toward the processing target substrate and a reflection direction toward the second mirror,
the first optical path is configured to guide the light outputted from the light source unit to the processing target substrate via the first mirror and configured to guide the reflection light from the processing target substrate to the light detection unit, and
the second optical path is configured to guide the light outputted from the light source unit to the light detection unit via the first mirror and the second mirror.

4. The process monitoring device of claim 3, further comprising:
an optical fiber cable configured to guide the light outputted from the light source unit to the first mirror,
wherein the first optical path is configured to guide the light outputted from the light source unit to the processing target substrate via the optical fiber cable and the first mirror, and configured to guide the reflection light from the processing target substrate to the light detection unit via the first mirror and the optical fiber cable, and
the second optical path is configured to guide the light outputted from the light source unit to the second mirror via the optical fiber cable and the first mirror, and configured to guide the reflection light from the second mirror to the light detection unit via the first mirror and the optical fiber cable.

5. The process monitoring device of claim 1,
wherein the controller is configured to analyze the structure of the processing target substrate by correcting the intensity information of the light detected by the light detection unit via the first optical path based on a difference between the intensity information of the light detected by the light detection unit via the second optical path and intensity information of light detected by the light detection unit via the second optical path at the time of starting a process.

6. The process monitoring device of claim 1,
wherein the light generated by the light source unit has a wavelength equal to or smaller than about 300 nm.

7. A process monitoring method of investigating a structure of a processing target substrate by irradiating light to a surface of the processing target substrate provided within a processing vessel of a substrate processing apparatus and detecting reflection light from the processing target substrate, the process monitoring method comprising:
a first optical path passing process that guides light outputted from a light source unit to the processing target substrate and guides the reflection light from the processing target substrate to a light detection unit configured to detect an intensity of light;
a second optical path passing process that guides light outputted from the light source unit to the light detection unit without allowing the light to pass the processing target substrate; and
an analyzing process that analyzes the structure of the processing target substrate by correcting intensity information of the light detected by the light detection unit through the first optical path passing process based on intensity information of the light detected by the light detection unit through the second optical path passing process,
wherein a first optical path through which the light passes in the first optical path passing process and a second optical path through which the light passes in the second optical path passing process are formed to have the same light propagation characteristic.

8. The process monitoring method of claim 7,
wherein each of the first optical path and the second optical path includes an optical fiber cable, and the optical fiber cables are made of the same material and have the same total length.

9. The process monitoring method of claim 7,
wherein the first optical path passing process includes:
guiding the light outputted from the light source unit to a first reflection member configured to change a reflection direction of the light;
reflecting the light toward the processing target substrate by the first reflection member; and
guiding the reflection light from the processing target substrate to the light detection unit,
the second optical path passing process includes:
guiding the light outputted from the light source unit to the first reflection member;
reflecting the light from the first reflection member toward a second reflection member configured to further reflect the reflection light from the first reflection member; and
guiding the reflection light from the second reflection member to the light detection unit, and
wherein the first reflection member is controlled to periodically change the reflection direction of the light between a reflection direction toward the processing target substrate and a reflection direction toward the second reflection member.

10. The process monitoring method of claim 9,
wherein, in the first optical path passing process, the reflection light from the processing target substrate is guided to the light detection unit via the first reflection member, and
in the second optical path passing process, the reflection light from the second reflection member is guided to the light detection unit via the first reflection member.

11. The process monitoring method of claim 7,
wherein the analyzing process includes:
a first measurement process that measures an intensity of the light detected by the light detection unit through the first optical path passing process;
a second measurement process that measures an intensity of the light detected by the light detection unit through the second optical path passing process;
a calculation process that calculates a light intensity difference between an intensity of light detected by the light detection unit through the second optical path passing process at the time of starting a process and the intensity of the light measured in the second measurement process;
a correction process that corrects the intensity of the light measured in the first measurement process based on the light intensity difference calculated in the calculation process; and
a structure analyzing process that analyzes the structure of the processing target substrate based on the corrected intensity of the light.

12. A substrate processing apparatus, comprising:
a processing vessel configured to perform therein a plasma process on a processing target substrate;
a mounting table provided in the processing vessel and configured to mount thereon the processing target substrate;
a gas supply unit configured to supply a processing gas into the processing vessel;
a plasma generating unit configured to generate plasma within the processing vessel; and
a process monitoring device configured to investigate a structure of the processing target substrate by irradiating light to a surface of the processing target substrate and detecting reflection light from the processing target substrate,
wherein the process monitoring device comprises:
a light source unit configured to generate and output light;
a light detection unit configured to detect an intensity of light inputted from an outside thereof;
a first optical path configured to guide the light outputted from the light source unit to the processing target substrate and guide the reflection light from the processing target substrate to the light detection unit;
a second optical path that is formed to have a light propagation characteristic equivalent to that of the first optical path and guides light outputted from the light source unit to the light detection unit without allowing the light to pass the processing target substrate; and
a controller configured to correct intensity information of the light detected by the light detection unit via the first optical path based on intensity information of the light detected by the light detection unit via the second optical path, and configured to analyze a structure of the processing target substrate.
